(19) United States
(12) Patent Application Publication
(10) Pub. No.: US 2025/0328704 A1
(43) Pub. Date: Oct. 23, 2025

(54) SYSTEMS AND METHODS FOR AUTONOMOUS POWER GRID ORCHESTRATION

(71) Applicant: ThinkLabs AI, Inc., Toronto (CA)

(72) Inventors: Joshua Wong, Toronto (CA); Neal Vali, Toronto (CA); Gang Zheng, Toronto (CA); Reza Roofegari Nejad, Toronto (CA); Gauravdeep Randhawa, Toronto (CA)

(73) Assignee: ThinkLabs AI, Inc., Toronto (CA)

(21) Appl. No.: 19/170,667

(22) Filed: Apr. 4, 2025

Related U.S. Application Data
(60) Provisional application No. 63/575,353, filed on Apr. 5, 2024.

(51) Int. Cl. G06F 30/18

(52) U.S. Cl. CPC G06F 30/18

(57) ABSTRACT

A system for autonomously facilitating monitoring and orchestration of operations and planning of a power grid includes one or more machine learning models for executing a digital representation of the power, determine operational states of the power grid, and cause the digital representation of the power grid to update based on the determined operational states of the power grid. The system may determine the operational states of the power grid by receiving data associated with a subset of nodes of the power grid and determine the states of each node of the power grid based on the data received associated with the subset.

### CROSS-REFERENCE TO RELATED APPLICATIONS

This application claims priority under 35 U.S.C. § 119(e) to and is a non-provisional application of U.S. Patent Application Ser. No. 63/575,353, filed Apr. 5, 2024, entitled “SYSTEMS AND METHODS FOR AUTONOMOUS POWER GRID ORCHESTRATION,” the entire contents of which are incorporated herein by reference.

### SUMMARY

The energy system in various regions is undergoing massive transformations due to electrification, decarbonization, decentralization, and digitalization. Further, aspects like renewable energy integration, electric vehicle adoption, electrification of heating, proliferation of distributed energy resources (DERs), demand flexibility, adverse weather events, and cybersecurity have presented compounding challenges for energy system and power grid operation and orchestration. Not managing the grid effectively through these compounding challenges may have a major impact on the reliability, affordability, and level of service the grid provides to electricity customers. As such, traditional operational and engineering tools that rely on human operation and orchestration, and tools that are based on rules-based management and historical worst-case scenario studies such as Advanced Distribution Management System (ADMS) and Distributed Energy Resource Management System (DERMS) are not enough to keep up with the pace of change and timeliness of decision-making.

According to an aspect described herein, a system for facilitating monitoring and orchestration of operations and planning of a power grid is provided. In some embodiments, the system includes: a digital representation of the power grid having a plurality of nodes and a plurality of lines connecting the plurality of nodes, each node of the plurality of nodes representing a respective electrical component of the power grid and each line of the plurality of lines representing an electrical connection between respective electrical components of the power grid; and one or more machine learning models configured to: execute the digital representation of the power grid; determine an operational state of the power grid by: receiving as input, data associated with at least a subset of the plurality of nodes wherein the data is indicative of a state of each node of the subset of the plurality of nodes; and determining a state of each node of the plurality of nodes based at least in part on the received data associated with at least a subset of the plurality of nodes; and cause the digital representation of the power grid to update based on the determined operational state of the power grid.

In some embodiments, the one or more machine learning models are further configured to cause the digital representation of the power grid to update substantially in parallel with the operations of the power grid. In some embodiments, at least one of the one or more machine learning models is trained on a plurality of scenarios including at least one of: historical scenarios, real time scenarios, forecasted scenarios and/or synthetic scenarios. In some embodiments, the at least one of the one or more machine learning models is further configured to learn continuously based at least in part on the received data and/or one or more scenarios of the plurality of scenarios.

In some embodiments, the one or more machine learning models are further configured to determine one or more actions for operating the power grid based on the determined operational state of the power grid. In some embodiments, the one or more actions include at least one relief action responsive to the determined operational state of the power grid when the determined operational state of the power grid indicates that the power grid is experiencing an operational violation. In some embodiments, the at least one relief action is determined in response to an indication that the power grid is experiencing at least one of: an overvoltage violation, and undervoltage violation, a reverse power flow, and/or a current violation. In some embodiments, determining one or more actions for operating the power grid based on the determined operational state of the power grid comprises using at least one of the one or more machine learning models trained using one or more of: standard operating practices, business rules, policies, and/or previous user experiences.

In some embodiments, at least one of the one or more machine learning models configured to execute the digital representation is a physics-informed machine learning model trained using a physics-based engineering model. In some embodiments, the physics-informed machine learning model is a Graph Neural Network (GNN). In some embodiments, the physics-informed machine learning model is a foundational model trained on a first training data set to execute the digital representation of the power grid to represent a first circuit; and the physics-informed machine learning model is further configured to be updated to execute the digital representation of the power grid to represent a second circuit by further training the physics-informed machine learning model on a second training data set having less training data than the first training data set.

In some embodiments, the system further comprises a forecasting tool, wherein the one or more machine learning models configured to execute the digital representation of the power grid is configured to use the forecasting tool as input to execute a predicted digital representation of the power grid by determining a predicted operational state of the power grid and causing the digital representation of the power grid to update based on the predicted operational state of the power grid.

In some embodiments, the one or more machine learning models are further configured to validate the digital representation of power grid. In some embodiments, validating the digital representation of the power grid comprises simulating an event with a known outcome on the digital representation to determine a model outcome and comparing the model outcome with the known outcome. In some embodiments, comparing the model outcome with the known outcome comprises determining an error metric and a confidence interval for each node of the plurality of nodes of the digital representation. In some embodiments, the digital representation is validated when the error metric is below a certain threshold and/or the confidence interval encompasses a zero percent error.

According to an aspect described herein, a method for facilitating monitoring and orchestration of operations and planning of a power grid is provided. In some embodiments, the method comprises: receiving data associated with at least a subset of a plurality of nodes of the power grid, the data being indicative of a state of each node of the subset of the plurality of nodes; providing the received data as input to one or more machine learning models configured to generate a digital representation of the power grid to determine an operational state of the power grid; and generating, using the one or more machine learning models, a digital representation of the power grid based on the determined operational state of the power grid.

In some embodiments, the one or more machine learning models are pre-trained on a central network grid and further fined-tuned on a decentral subset of the grid when deployed at one or more components of the grid.

In some embodiments, the method further comprises: updating the digital representation of the power grid when new data associated with the subset of the plurality of nodes of the power grid is received, wherein updating the digital representation is performed substantially in parallel with operations of the power grid.

According to an aspect described herein, a non-transitory computer-readable medium storing computer executable instructions that when executed by a processor, cause the processor to perform a method for facilitating monitoring and orchestration of operations and planning of a power grid is provided. The method comprises: receiving data associated with at least a subset of a plurality of nodes of the power grid, the data being indicative of a state of each node of the subset of the plurality of nodes; providing the received data as input to one or more machine learning models configured to generate a digital representation of the power grid to determine an operational state of the power grid; and generating, using the one or more machine learning models, a digital representation of the power grid based on the determined operational state of the power grid.

According to an aspect described herein, a system for monitoring operation of a power grid is provided. The system comprises: one or more machine learning models configured to generate a digital representation of the power grid based at least in part on measurements indicative of a state of at least a portion of the power grid; and a processing unit configured to: request an updated digital representation of the power grid from the one or more machine learning models, the updated digital representation of the power grid comprising information indicative of one or more operational states of the power grid; determine one or more recommended actions for operating the power grid based on the information indicative of the one or more operational states of the power grid; and output the one or more recommended actions.

In some embodiments, the processing unit is further configured to: determine an indication that the power grid is experiencing an operational violation based on the updated digital representation and the one or more operational states of the power grid. In some embodiments, the operational violation includes at least one of: an overvoltage violation, undervoltage violation, current violation, power violation, reverse power flow violation, and/or congestion violation. In some embodiments, determining one or more recommended actions comprises determining one or more relief actions to be executed responsive to the indication of the operational violation of the power grid by: providing the digital representation and indication of the operational violation as input to a machine learning model configured to determine the one or more relief actions, wherein the machine learning model is trained to determine the one or more relief actions using one or more of: standard operating practices, business rules, policies, and/or previous user experiences. In some embodiments, the processing unit is further configured to autonomously execute at least one of the one or more relief actions.

In some embodiments, the processing unit is further configured to execute the one or more machine learning models configured to generate the digital representation. In some embodiments, the processing unit is further configured to receive the measurements indicative of the state of at least the portion of the power grid and provide the measurements as input to the one or more machine learning models.

According to an aspect described herein, a system for validating a digital representation of a power grid is provided. In some embodiments, the system comprises: one or more machine learning models configured to provide the digital representation of the power grid based at least in part on measurements indicative of a state of at least a portion of the power grid; and a processing unit configured to validate the digital representation of the power grid provided by the one or more machine learning models, wherein validating the digital representation comprises: simulating an event of the power grid using digital representation of the power grid to produce a simulated outcome, the simulated event having a known outcome; determining at least one model error metric and model confidence interval at least in part by comparing the simulated outcome and the known outcome; and providing the at least one error metric to a user of the system.

In some embodiments, determining the at least one model error metric by comparing the simulated outcome and the known outcome comprises: determining an error metric and a confidence interval for each node of a plurality of nodes in the digital representation by comparing, for each node of the plurality of nodes, a simulated state of the node indicated by the simulated outcome and a known state of the node indicated by the known outcome. In some embodiments, the at least one model error metric is a composite error metric determined based in part of the error metrics and confidence intervals determined for each node of the plurality of nodes in the digital representation.

In some embodiments, the processing unit is further configured to: determine that the digital representation is valid when the at least one model error metric is below a threshold error value and/or the model confidence interval encompasses a zero percent error value.

According to an aspect described herein, a user interface for monitoring and orchestrating operations of a power grid is provided. In some embodiments, the user interface comprises a visual module, executed by at least one processor, configured to: receive a digital representation of the power grid and information associated with the power grid from at least a first machine learning model and cause to display a visual representation of the power grid based at least in part on the digital representation of the power grid and information associated with the power grid; and a chat module, executed by at least one processor, configured to: receive user input indicative of a request for information from the user; generate an output based at least in part on a determined operational state of the power grid and at least one of standard operating practices, business rules, policies, and/or previous operator experiences wherein the determined operational state of the power grid is determined based on the digital representation of the power grid and information associated with the power grid; generate, using a second machine learning model, a response to the request for information from the user based on the user input; and cause to display the response and/or output to the user.

In some embodiments, the second machine learning model comprises a large language model or a large action model. In some embodiments, the visual module is configured to cause to display indications of one or more operational violations exhibited by the power grid, wherein the one or more operational violations are determined based on the digital representation of the power grid and information associated with the power grid.

In some embodiments, the user interface further comprises an execution module, executed by at least one processor, configured to: receive one or more recommended actions for optimizing operation of the power grid from a third machine learning model based on the information associated with the power grid received from the first machine learning model; cause to display the one or more recommended actions for optimizing operation of the power grid to the user; and cause to execute the one or more recommended actions for optimizing operation of the power grid based at least in part on a user action in response to viewing the one or more recommended actions for optimizing operation of the power grid to the user.

In some embodiments, the execution module is configured to cause to display one or more selectable visual indicators configured to toggle the execution module between an autonomous operation mode and a semi-autonomous operation mode responsive to the user selecting at least one of the one or more selectable visual indicators. In some embodiments, causing to execute the one or more recommended actions for optimizing operation of the power grid comprises: when the execution module is in the autonomous operation mode: executing the one or more recommended actions; and suspending the execution of the one or more recommended actions responsive to user input; and when the execution module is in the semi-autonomous operation mode: suspending the execution of the one or more recommended actions until user input is received; and executing the one or more recommended actions responsive to the user input.

In some embodiments, when the execution module is in the autonomous operation mode, the execution module is configured to cause to display a selectable visual indicator configured to suspend execution of the one or more recommended actions responsive to user input comprising selection of the selectable visual indicator configured to suspend the execution. In some embodiments, when the execution module is in the semi-autonomous operation mode, the execution module is configured to cause to display a selectable visual indicator configured to trigger execution of the one or more recommended actions responsive to user input comprising selection of the selectable visual indicator configured to trigger the execution.

Still other aspects, embodiments, and advantages of these exemplary aspects and embodiments, are discussed in detail below. Any embodiment disclosed herein may be combined with any other embodiment in any manner consistent with at least one of the objects, aims, and needs disclosed herein, and references to “an embodiment,” “some embodiments,” “an alternate embodiment,” “various embodiments,” “one embodiment” or the like are not necessarily mutually exclusive and are intended to indicate that a particular feature, structure, or characteristic described in connection with the embodiment may be included in at least one embodiment. The appearances of such terms herein are not necessarily all referring to the same embodiment. The accompanying drawings are included to provide illustration and a further understanding of the various aspects and embodiments and are incorporated in and constitute a part of this specification. The drawings, together with the remainder of the specification, serve to explain principles and operations of the described and claimed aspects and embodiments.

### BRIEF DESCRIPTION OF THE DRAWINGS

The accompanying drawings are not intended to be drawn to scale. In the drawings, each identical or nearly identical component that is illustrated in various figures may be represented by a like numeral. For purposes of clarity, not every component may be labeled in every drawing. In the drawings:

FIG. 1 is a block diagram of an example system for autonomous power grid orchestration, according to some embodiments;

FIG. 2 depicts a flow chart illustrating functions of various components of the system of FIG. 1, according to some embodiments;

FIG. 3A depicts a schematic representation of a digital representation of the power grid, according to some embodiments;

FIG. 3B depicts a flowchart of an example method for generating power grid information, according to some embodiments;

FIG. 4 depicts an example insight module for performing autonomous power grid orchestration functions, according to some embodiments;

FIG. 5 depicts an example solution module for performing autonomous power grid orchestration functions, according to some embodiments;

FIG. 6 depicts an example method for autonomous orchestration of a power grid experiencing an operational violation, according to some embodiments;

FIG. 7 depicts an example validation module for performing autonomous power grid orchestration functions, according to some embodiments;

FIG. 8A depicts an example user interface for performing autonomous power grid orchestration functions, according to some embodiments;

FIG. 8B depicts an example chat interface for performing autonomous power grid orchestration functions, according to some embodiments;

FIG. 9 depicts an example computer-based system on which the system of FIG. 1 may be implemented, according to some embodiments.

### DETAILED DESCRIPTION

As discussed above, the energy system is undergoing profound transformations due to electrification, decarbonization, decentralization, and digitalization which have caused the grid to become increasingly complex, unpredictable, and volatile. As such, the grid is becoming too complicated for traditional human operation, and developments in computational operation such as the Advanced Distribution Management System (ADMS) and Distributed Energy Resource Management System (DERMS) may not be enough on their own to keep up with the increasing complexity. Namely, rules-based management and worst-case scenario studies cannot keep up with the pace of change and rapid decision making. The inventors have recognized and appreciated a number of problems that underpin the difficulty in adapting conventional methods and techniques to this transformation and increasing complexity.

The inventors have recognized and appreciated a number of operational challenges that present issues in adapting conventional methods and techniques. First, the grid itself has become increasingly complex with the electrification of various analog and mechanical systems, such as the increase in electric vehicle usage, solar generators, and other distributed energy resources (DERS), as well as increasing load of the grid by facilities such as data centers. As such, power flow in the grid has similarly become increasingly complex and volatile, as the mathematical model of the grid changes with the DERs connected to the grid. Further, the problems presented by the increasing complexity of the grid may be compounded by issues with the availability and quality of data from the grid. The data available to use in conventional operation and orchestration methods and techniques suffers from poor data quality to run engineering analyses in an operational time frame. The data actually measured from the grid is sparse, where less than 0.1% of the distribution grid may be actually measured. This data may further be kept in data silos, limiting accessibility to the data and analytics for people outside of the operational control rooms.

As such, conventional methods and techniques for grid operation and orchestration may be limited in the ability to adjust and adapt to the complexity of the grid. Orchestration of the power grid may include coordinated analysis, decision, and actions across various aspects of the power grid, including, but not limited to, planning, operational-planning, generation, transmission, distribution, and loads; centralized (e.g., enterprise or cloud), hybrid decentralized, and decentralized intelligence. Conventional computation techniques for grid operation and orchestration typically use rules-based management and worst-case scenario studies to model and determine the proper relief actions for violations of grid operations. Rules-based management and scenario studies alone may be insufficient to adapt to the rapid changing and complex state of the current grid and lack scalability, as they tend to rely on human actors and experiences to generate solutions. Conventionally, design fixes may be implemented and may run until failure several years later, which may be inefficient for the rapid changes the modern grid may be experiencing. Further, physics-based modelling on its own may be computationally slow and data sensitive when modelling the power flow of the grid. Pure physics models may run into trouble when trying to perform certain power flow modelling and optimization techniques like the security constrained alternating current optimal power flow equations (SC-ACOPF). The issues with the pure physics models may similarly be compounded by the scarcity of data and may not be able to fill in the gaps of data that are not measured.

Accordingly, the inventors have recognized that the capabilities of artificial intelligence (AI) and machine learning (ML) can provide a faster and more accurate operational model of the grid than the pure physics models of conventional techniques, even when the data inputted into the model is imperfect. Using AI/ML to orchestrate the operation of the power grid provides a number of advantages. For one, the use of AI/ML provides the speed, scalability, and adaptability to keep up with the rapidly evolving grid that the pure physics models of conventional techniques lack. Further, the AI/ML-based techniques address the sparse, low-quality data typically generated by the power grid by being pretrained on a multitude of scenarios to be ready for complexity and sparse data, as well as provide a probabilistic evaluation of the grid rather than the deterministic pure physics models. AI/ML additionally minimizes the reliance on human actors who may exhibit human error by being able (1) to learn with new data and experiences, (2) both solve and generate solutions for operational orchestration of the power grid, and (3) execute actions in a supervised or autonomous mode as the prime actor. In that way, the AI/ML-based power grid orchestration systems and techniques described herein may provide a faster, scalable, and more reliable method to perform orchestration functions of the power grid.

However, pure AI/ML techniques may similarly have several drawbacks. For example, an AI model may exhibit hallucinations, or nonsensical outputs, when there is not enough data. As such, the inventors have developed systems and methods to address the various issues with the rapidly transforming energy system, the details of which will be described further herein.

In some aspects of the technology described here, the inventors have developed systems for monitoring and diagnosing power grid operations to enable and accelerate the grid's role as a centralized and decentralized intelligence platform for the energy transition. By leveraging the capabilities of AI and ML techniques with physics-informed modelling, the inventors have developed reliable and accurate modelling and diagnostic technologies that can provide real time, or near-real time, scenario-based, and accurate models of the power grid, even with access to only the limited amount of potentially imperfect grid data that may be available.

According to some aspects, a system for monitoring the operation of a power grid may be provided. The system may include one or more machine learning models for modelling the current state of the power grid in real-time or near real time. For example, the one or more machine learning models may provide a digital representation of the power grid at a particular point in time and/or based on a particular set of data. The system may receive measurements and data associated with at least a subset of the power grid, for example, the subset of the power grid that is actually measured. The data associated with at the subset of the power grid may have its own range of accuracy as well, to be refined as the machine learning model updates the model of the power grid. In some examples, the received measurements and data may be indicative of the state of the subset of the power grid after the particular point in time, for example, the model may update to model a current state of the grid after a few seconds or every few seconds to obtain a real-time or near real-time model of the power grid. The one or more machine learning models may use the received measurements and data associated with the subset of the power grid to update the digital representation to represent the power grid at the later point in time and/or based on the received measurements and data. In some examples, the machine learning model may be operatively coupled to a forecasting tool and may predictively model the state of the grid at a future point in time using the forecasting tool.

In some examples, the system may further include a processing unit, for example another machine learning model, to process the received measurements and data along with the digital representation to monitor the state of the power grid. Based on the received measurements, data, and digital representation, the processing unit may determine whether the power grid is operating properly or experiencing a violation. In some examples, the processing unit may determine the states of the power grid system, for example, the real power, reactive power, current, voltage, or a combination thereof. The states of the power grid system may be determined for each phase (e.g., the three phases of three phase alternating current (AC)) and node (e.g., bus) of the power grid system. In some examples, the processing unit may be configured to determine one or more operational metrics. For example, the processing unit may monitor and determine utilization and constraints of different assets like DERs and other electrical components. Additionally or alternatively, the processing unit may determine whether the power grid is operating properly or is experiencing or nearing (e.g., during a time of high electrical congestion) an operational violation, including but not limited to, a capacity violation, a voltage threshold violation, and a reverse power flow, or any other suitable operational metric.

In some examples, the system may further include a processing unit, for example another machine learning model, to provide recommended relief actions if the system determines that the power grid is experiencing some type of operational violation, for example, a capacity violation or a reverse power flow. Additionally or alternatively, the processing unit may be configured to determine optimization actions to optimize the power grid operation, for example, improve voltage profile, reduce losses, and/or increase the ability to connect various DERs. In some examples, the processing unit may implement a machine learning model trained to determine various recommended relief actions based at least in part on the violation the power grid is experiencing. For example, the machine learning model may be trained on historical grid events and how those events were handled, standard operating procedures, simulated events, business rules, and policies. In some embodiments, the machine learning model may be trained via reinforcement learning with or without human feedback to derive generative solutions and relief actions. The machine learning model may determine various relief actions to mitigate the violation that the power grid is experiencing, including, but not limited to, network switching, generation curtailment, storage dispatch, demand response, and pricing actions.

The inventors have recognized and appreciated that there should be some level of human involvement in the decision-making process for monitoring grid operations and executing particular relief actions. Accordingly, the inventors have developed and provided a system for integrating the various monitoring and diagnostic functions described herein into a user interface that can support semi-autonomous, supervised autonomous, or autonomous monitoring and diagnostic functions. However, the inventors have further recognized and appreciated that certain operators may have less experience than others. As the workforce ages towards retirement and a labor shortage makes it more difficult to hire more technically experienced operators, an interface with supportive functionality may be beneficial to support less experienced operators as well as mitigate the effects of a lack of available operators. Further, the grid, as well as the various analyses described herein may generate a multitude of data that may be difficult to parse and/or visualize in raw form. As such, the user interface may enable an operator to easily parse the data to monitor the operation of the power grid and evaluate the various actions for operating the power grid generated by the system as described herein.

In some aspects of the technology, a system for supporting a user interface for monitoring and diagnosing power grid operations may be provided. The system may include a processor for receiving various information and data to display to an operator, and a display for displaying the various information and data to the operator. In some examples, the system may receive with the processor, outputs of the one or more machine learning models and/or processing units described above and further herein. For example, the system may receive the digital representation provided by the one or more machine learning models. In some examples, the system may receive the determined states of the power grid like real power, reactive power, current, and/or voltage. In some examples, the system may receive an indication of an operational metric (e.g., operational violation, asset utilization) that the power grid may be experiencing along with data associated with that operational metric, for example, affected grid components and number of customers affected. In some examples, the system may receive recommended relief actions for mitigating an operation violation or otherwise address the operational metric.

The processor may cause the system to display, using the display, the various information and data received. For example, the system may display a visual representation of the grid based at least in part on the digital representation of the grid and the determined states of the power grid. In some examples, the visual representation may additionally include an indication that the grid is experiencing a violation or nearing an operational violation, for example, by changing the color of the component of the grid that are affected by the violation. Additionally or alternatively, in some examples, the system may display the various states of the power grid and/or the indication of the violation that the grid may be experiencing separately from the visual representation of the grid. In some examples, the system may additionally or alternatively display other metrics associated with the operation of the power grid, for example, network switching plans, power generated from various DERs of the grid, total number of violations, type of violations, impact of violations or any other suitable metric. For example, the user interface may include an alarm management module to display any or all of the above identified metrics.

In some examples, the system may support an operator of the system by providing a chat function. In some examples, the chat function may include a machine learning model to support the operator in monitoring, diagnosing, and making decisions with respect to grid operation and orchestration. For example, the chat function may present the operator with recommended actions such as reviewing relief actions for violations that are similar to a violation that the grid may be experiencing. By providing an AI/ML powered chat interface, the system may support less experienced operators that may be early in their training and who may not have the experience to ask some or all the right questions to best understand the operation, diagnosis, and recommended relief actions provided by the system.

In some examples, the system may further display the various activity of the other related systems described herein, for example, when the system is determining the states of the power grid to update the digital representation, determining recommended relief actions, or any other suitable activity. In that way, the system may support various modes of operation of the system with varying levels of operator interaction, including semi-autonomous, supervised autonomous, and/or autonomous modes of operation.

The inventors have further recognized and appreciated that everyday operations of the power grid or mitigating various violations may involve dangerous tasks presenting a risk to linemen working on various electrical components of the grid, such as high voltage wires. This may be especially true, if the underlying data or analysis is incorrect or untrustworthy. Further, validation of the model may help operators and grid workers carry out traditional engineering functions and analysis by validating and correcting any errors. As such, the inventors have recognized that providing a way to accurately validate the various models described above to ensure the accuracy of the models and minimize risk to the linemen working on the various electrical components of the grid may be beneficial. Accordingly, the inventors have developed systems and methods for validating the various models of the monitoring and diagnostic systems described herein.

In some examples, validating the various models may include running one or more simulated events on the models. The simulated events may have known outcomes, for example, the various states of the grid including real power, reactive power, current, and voltage as a result of the simulated event may be known, or the proper recommended relief actions as a result of the simulated event may be known. The models may determine a number of outputs as a result of the simulated event, for example, the real power, reactive power, current, and voltage, or a particular relief action. The system may then compare the outputs determined by the model with the known outcomes of the simulated event to determine one or more model error metrics associated with the outputs determined by the model. The model error metrics may be used to validate the model. For example, the model error metrics may be expressed as a percent error and the model(s) may be determined to be valid if the model error metric is under a threshold percent error. In some examples, the model error metrics may include a confidence interval, and the model(s) may be determined valid if the confidence interval encompasses a zero percent error. In some examples, the model(s) may be determined to be valid if both the percent error of the model error metric is lower than a threshold percent error and the confidence interval of the model error metric encompasses a zero percent error.

Having described generally various aspects and functionality of the systems provided herein, further details of the various components and functions will be provided further herein. Although different aspects, components, and functions may be described separately, it can be appreciated that the various aspects, components, and functions may be provided as one integrated system, or may be provided as multiple systems including various combinations of the aspects, components, and functions. In some examples, an integrated system may be provided to monitor and diagnose the state and operation of the power grid, determine recommended relief actions, and validate the various models of the system. Alternatively, in some examples, a first system may be provided to monitor and diagnose the state of the power grid, a second system may be provided to determine recommended relief actions, and a third system may be provided to validate the various models of the systems. However, any combination of the various aspects, components, and functions described herein may be suitable.

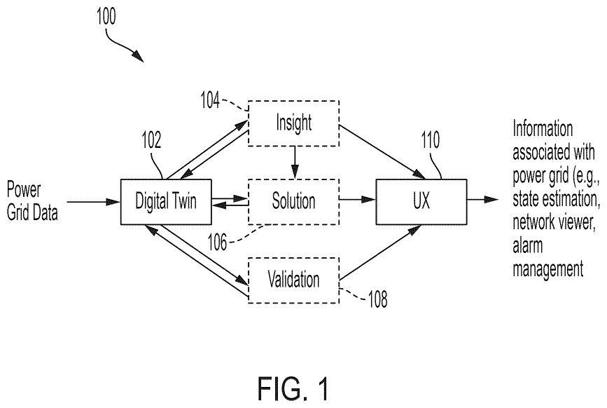

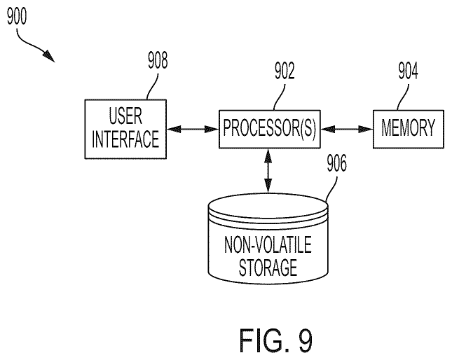

In some aspects, a system may be provided configured to perform one or more of the various functions described herein, including, monitoring and diagnosing the operation of the power grid, determining recommended relief actions for mitigating various operational violations of the power grid, validating one or more of the models of the system, and/or providing a user interface to support operators of the power grid with various operational and diagnostic functions. FIG. 1 is a block diagram of an example system 100 for autonomous power grid orchestration, according to some embodiments. System 100 includes a digital twin 102, insight module 104, solution module 106, validation module 108, and user interface 110, each of which will be described in further detail below. In some examples, the system 100 may be implemented by a computer, for example, a computer on the premise of an operator control room. Each of the different components may be executed by one or more processors (e.g., processors 910 of FIG. 9) in any suitable manner. In some examples, the system 100 may be implemented by a distributed computing resource and the various models described herein may be hosted by the distributed computing resource, for example, a private cloud, a public cloud, a hybrid cloud, or as distributed intelligence devices, the components of which may transmit and receive data over a communication network. In some examples, the system 100 may include one or more machine learning models configured to perform the various functions described herein.

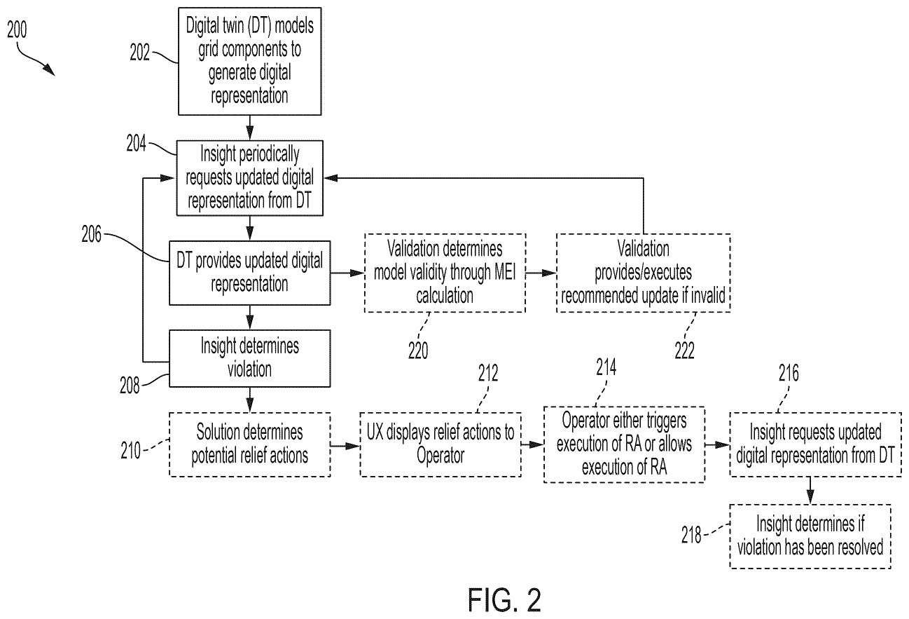

FIG. 2 depicts a flow chart of an example method 200 illustrating functions of various components of the system of FIG. 1, according to some embodiments. At act 202 of method 200, the digital twin module (e.g., digital twin 102) models various grid components to generate a digital representation of at least a section of the power grid. For example, as discussed further herein, digital twin 102 may execute one or more machine learning models (referred to herein as digital representation models) for performing power flow modelling and/or distribution system state estimation (DSSE) of the various components of the power grid when data regarding the components of the power grid is received. Power flow modeling may be performed to perform planning or operational planning functions whereas DSSE may be performed to conduct real-time, or near real-time, power flow state analysis. In some embodiments, step 202 may comprise having the digital twin update an existing digital representation when new or updated data is received.

At act 204, the insight module 104 requests power flow information from the digital twin 102. The power flow information may be used by insight module to perform any monitoring or diagnoses functions as described herein.

The request from the insight module 104 may, at act 206, cause the digital twin 102 to generate an updated digital representation by performing power flow modeling or DSSE based on the more recently received data regarding the components of the power grid. In some embodiments, the request from insight module 104 may cause digital twin 102 to request updated data from components of the power grid and may base the updated power flow or DSSE function on the updated data. Additionally, in some embodiments, DSSE may further determine whether the received data is bad data. Once the new power flow information is generated, digital twin 102 may provide the new power flow information to the insight module 104.

Having received new power flow information (e.g. in real-time or near-real-time with respect to the operation of the power grid), at act 208, the insight module 104 may determine that the power grid is experiencing one or more operational violations. For example, based on the power flow information, insight module 104 may determine one or more of an overvoltage violation, reverse power flow violation, asset utilizations, or any other suitable monitoring and/or diagnostic information. In some embodiments, the insight module may determine the one or more operational violations by providing the power flow information as input to a machine learning model. The machine learning model may be trained to determine that the power grid is experiencing an operational violation based on one or more aspects of the power flow information.

When insight module 104 determines that the power grid is experiencing a violation (e.g., overvoltage, power flow), at act 210, solution module 106 may determine one or more potential relief actions for mitigating or resolving the violation(s). Insight module 104 may provide the power flow information and information regarding the violation to the solution module 106. Solution module 106 may determine the one or more relief actions based on the power flow information and information regarding the violation(s). In some embodiments, solution module 106 may provide the power flow information and information regarding the violation(s) as input to a machine learning model to determine the one or more potential relief actions. The machine learning model may be trained to determine the one or more potential relief actions based on operating procedures, business rules policy, worst-case analysis, and historical actions (e.g., prior relief actions used to mitigate prior violations).

At act 212, the solution module 106 provides at least some of the one or more relief actions to a user interface 110 for display to an operator. User interface 110 may display the potential relief actions and any information associated with the relief actions, for example, what violation it addresses.

At act 214, execution of at least one of the relief actions determined at act 210 may be triggered. As discussed further below, system 100 may be configured to operate in multiple different modes, including, but not limited to, a semi-autonomous mode, or an autonomous mode. In the semi-autonomous mode, execution of the relief action(s) may be in response to an input of the operator. For example, user interface 110 may display a selectable indicator configured to trigger execution of a relief action in response to an operator's selection of the indicator. In the autonomous mode, execution of the relief action(s) may be autonomous and may be performed without any input from the operator. However, user interface 110 may display a selectable indicator configured to suspend execution of the relief action(s) in response to an operator's selection, for example, in the event that the operator determines the relief action should not be performed.

After execution of the relief action at act 214, at act 216, insight module 106 may request updated power flow information (and/or an updated digital representation). This may be done in the same manner as described above with respect to acts 204 and 206.

Once the updated power flow model or DSSE is received from the digital twin, at act 218, insight module 106 may determine whether at least one of the one or more determined violations (determined at act 208) is resolved.

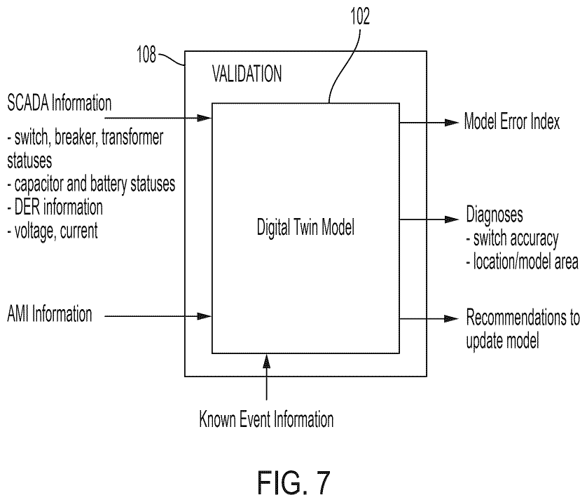

Separately, after the updated power flow information and digital representation is received from the digital twin 102 at act 206, the validation module 108 may determine the validity of the model at act 220. Validation module 108 may determine a model validity of the digital representation generated by digital twin 102 by evaluating a model error index (MEI) as described further herein with respect to FIG. 7 below.

Once the MEI is evaluated, at act 222, validation module 108 may determine and provide recommended actions and/or updates to the model if the digital representation is determined to be invalid. For example, in some embodiments, validation module 108 may determine that the model is invalid when the MEI is determined to be above a threshold error value (e.g., a percent-error threshold value). Once validation module 108 determines the digital representation is invalid, validation module 108 may determine on or more recommended actions for correcting the model, including but not limited to, network topology corrections (switches), asset phasing corrections, asset parameter corrections, new or undetected asset corrections.

It should be appreciated that method 200 depicted in the flowchart of FIG. 2 is for example purposes only and each of the acts of method 200 may be performed in conjunction, simultaneously, or nearly simultaneously with other acts of the method. For example, optional act 216 may not be a separate act from acts 204 and 206, and the determination done in act 218 may be performed based on the updated power flow information provided by digital twin 102 at act 206. Further, acts 220 and 222 may be performed at any suitable point in the method for example, before, simultaneously with, or after acts 210-218.

### AI Digital Twin

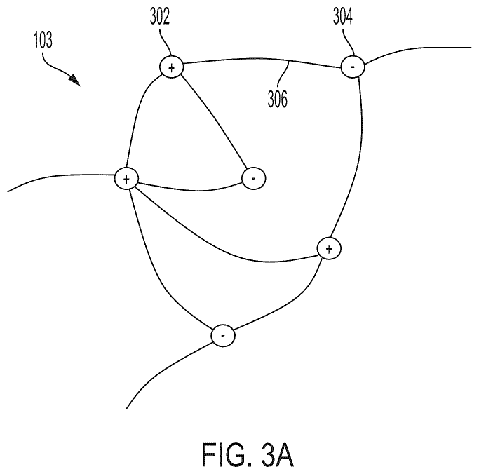

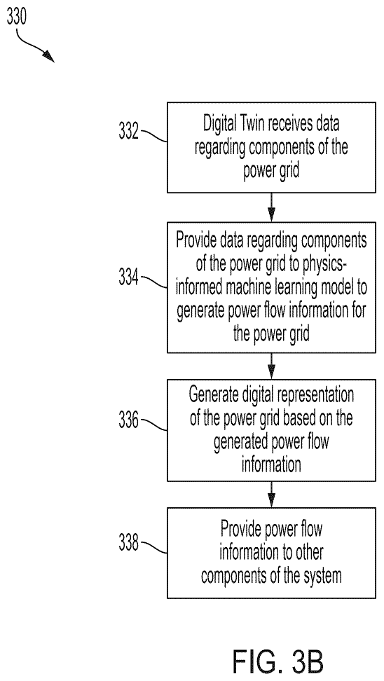

In some examples, at least one of the one or more machine learning models may be configured to provide a digital representation of the power grid. The at least one digital representation model may be configured to provide a digital representation of the power grid by modeling various grid components, including power generators, sinks, DERs, and interconnections, and any other suitable components. FIG. 3A depicts a schematic representation of a digital representation 103 of the power grid, according to some embodiments. Digital representation 103 includes a series of nodes (e.g., nodes 302 and 304) representing the various components of the power grid (e.g., generators, sinks, DERs) and connections 306 between the various nodes.

Additionally, the at least one digital representation model may further include as part of the digital representation a model of the power flow of the grid between the various components. For example, power generators may be represented as nodes of the model with a positive power output—for example, node 302—whereas power sinks may be represented as nodes of the model with a negative power output—for example, node 304. In that way, the at least one digital representation model may provide a model or simulation the transmission and distribution of power by the power grid. However, it should be appreciated that the digital representation model, may further analyze and determine various other metrics associated with monitoring and orchestrating operation of the grid, including but not limited to, load allocation, congestion, hosting capacity, operating envelopes, energy losses, asset utilization, dynamic asset ratings, and operating costs.

In some examples, the digital representation model executed by digital twin 102 may provide a digital representation of the entire power grid. In some examples, the digital representation model may provide a digital representation of a portion of the power grid. For example, the area of responsibility for the digital representation model may be determined by the operational utility company responsible for the portion of the power grid, may be determined as a region of high DER penetration, or may be determined as the geographic region covered by a particular operator desk, or may be determined in any other suitable manner. The digital representation model may provide a digital representation of a transmission grid, distribution grid, microgrid, one or an aggregate of various DERs including distributed generation, storage, and/or controllable loads, or a combination thereof.

The digital representation model executed by digital twin 102 may be a physics-informed machine learning model. For example, the digital representation model may be built to represent various physics-based processes and model various physics formulas, including, but not limited to, power flow equations, state estimation processes, and mathematical and AI/ML optimization processes. In some examples, the digital representation may be physics-informed by using physics and engineering-based equations to generate training data to train the machine learning model of the digital representation. For example, the digital representation model may be physics-informed based on various flow equations such as current-voltage flow equations (e.g., Kirchoff's Law):

$$I = Y V$$

where I is the current vector, V is the voltage vector, and Y is a y-impedance matrix of the system, and/or the power flow equations:

$${P}_{i} = \sum \vert {V}_{i} \vert \vert {V}_{k} \vert ( {G}_{i k} cos ( {θ}_{ik} ) + {B}_{ik} sin ( {θ}_{ik} ) )$$

$${Q}_{i} = \sum \vert {V}_{i} \vert \vert {V}_{k} \vert ( {G}_{i k} sin ( {θ}_{ik} ) + {B}_{ik} cos ( {θ}_{ik} ) )$$

where Pᵢ is the real power generated at bus i, Qᵢ is the reactive power, Gᵢₖ is the real component of the y-admittance matrix, Bᵢₖ is the imaginary part of the y-admittance matrix, and θᵢₖ is the phase difference between the bus i and bus k.

In some examples, the digital representation model executed by digital twin 102 may be physics-informed by hybridizing physics and engineering functions with machine learning functions to develop a robust analytic process. In some examples, the digital representation may be physics-informed by using a physics and engineering model to validate outputs of the machine learning model. In some examples, the digital representation may be physics-informed by using a machine learning model to provide a warm start to a physics and engineering model to provide an estimated starting point and reduce overall solve time for the physics and engineering model. In some examples, the digital representation may be physics informed using one or more of the above identified examples outlined above in combination.

Using a physics-informed machine learning model for the digital representation model may be better suited to model certain complex equations relevant to modeling the power grid than conventional techniques. For example, it may more quickly and accurately process and analyze the security constrained alternating current optimal power flow (SC-ACOPF) equations than a pure physics model, as the SC-ACOPF equations may include highly non-linear, non-convex optimization problems that conventional physics-based computational techniques may not handle quickly or accurately given the computational constraints and sparse data available from the power grid.

FIG. 3B depicts a flowchart of an example method 330 for generating power grid information, according to some embodiments. Method 330 may start at act 332 by receiving data regarding components of the power grid. The data received at act 332 may include grid topology information, for example, indicative of the various electrical connections between components of the power grid, as well as state measurements of a subset of the components of the power grid.

In some examples, the grid network topology of the digital representation model executed by the digital twin 102 may be determined by various information regarding the states of components and switches of the power grid and the interconnectivity between the various components. In some example, the various information may include, but is not limited to component impedance, ratings, limits, and connectivity. In some examples, the digital representation model may receive this information from an Advanced Distribution Management System (ADMS), power engineering simulation software, and/or a Geographic Information System (GIS). In some examples, the ADMS, simulation software, and/or GIS may be integrated with the system.

The digital representation model may additionally receive data indicative of measured states of at least a subset of components of the grid. In some embodiments, the digital representation model may receive data from the entire portion of the grid that is measured, even when that portion that is measured is just a subset of the entire grid. In some examples, the data may include, but is not limited to, the statuses of switches, breakers, transformers, capacitor, and batteries, DER information, and voltage, current, real power, and/or reactive power of the portion of the grid measured. In some examples, the digital representation model may receive this information from an ADMS, a GIS, Advanced Metering Infrastructure (AMI) devices in the grid, or Supervisory Control and Data Acquisition (SCADA) systems and devices of the grid, or a combination thereof.

At act 334, the received data regarding the components of the power grid may be provided to a machine learning model (e.g., physics-informed machine learning model, digital representation model) to generate power flow information for the power grid. For example, the machine learning model may be configured to determine the states (e.g., power, reactive power, current, voltage) of all of the nodes in the power grid based on the topological information of the power grid and the measured states of the subset of components of the grid received at act 332.

In some examples, the machine learning model (e.g., digital representation model) may determine the states of all of the nodes or components of the power grid by performing power flow modeling and/or distribution system state estimation (DSSE). The non-deterministic, probabilistic properties for minimizing error of a machine learning model may provide benefits over traditional mathematical computation state estimation for power flow or DSSE performance, which is typically more non-linear, complex, and based on sparser data than typical linear state estimation in transmission systems.

The digital representation model executed by the digital twin 102 may use the measurements received associated with various nodes (e.g., 302 and 304) of the digital representation of the grid to extrapolate and estimate the state of the other nodes of the digital representation of the grid. In some examples, the digital representation model may model input/output pairs of the power flow equations representing the power flow of the grid. For example, the input/output pairs of the power flow equations may be represented as Y-impedance matrices. The digital representation model may use as input, load vectors representing the real power and the reactive power at every bus of the power grid, which may be represented as a node of the digital representation, and may use matrix operations to determine output vectors representing the voltages and currents at every bus. A machine learning model may be able to form relationships between the real and reactive powers and the voltages and currents without using the mathematically complex impedance model. In some examples, the digital representation model may include more than one machine learning model. For example, the digital representation model may include a separate machine learning model for handling each of the various states to be determined, including a machine learning model configured to determine real power for each node, a machine learning model configured to determine reactive power for each node, a machine learning model configured to determine voltage for each node, and a machine learning model configured to determine for each node. Alternatively, in some examples, the digital representation model may be one machine learning model configured to determine all the states of the model, or two machine learning models each configured to determine two of the states, for example, one for real and reaction power, and another for voltage and current.

Some power grids may typically use three phase alternating current power to supply and distribute power throughout the grid, where three parallel lines carry three separate phase-shifted alternating currents. As such, in some examples, the input vectors may include load vectors representing the real and reactive powers for each of the three phases, and the output vectors may include voltages and currents for each of the three phases. Thus, the digital representation model may determine the various states of each node, at each phase, for the entire grid, or for the entire area of responsibility of the digital representation model, based on the sparse measured data. As such, digital representation 103 may provide, for each node (e.g., node 302 and 306), the real power, reactive power, current, and voltage for each of the three phases.

To provide an accurate state estimation of the entire grid based on the sparse data available to the system, the digital representation model executed by digital twin 102 may reliably estimate the states of each node of the digital representation of the grid. In some examples, the digital representation model may be trained on simulated events of the grid. In some examples, at least a subset of the simulated events used to train the digital representation model may be based on historical grid data and events. In some examples, at least a portion of the simulated events may include real-time events, forecasted events, and/or synthetic scenarios. To have a reliable model, the digital representation model may be trained on a large number of simulated events, for example, 1,000 simulated events, 10,000 simulated events, 25,000 simulated events, or any suitable number of simulated events. The events may be simulated, and the digital representation model may be trained using power flow simulation software, including but not limited to, OpenDSS, PSCAD, PSSE, Gurobi, GAMS, CYME, Synergi, PowerFactory, ADMS, pandapower, and/or DERMS. In some examples, certain hardware may be used to simulate the events and train the digital representation model including real-time digital simulators (RTDS), OpalRT, or any other suitable hardware. In some examples, the digital representation model may be continuously learning in real time once the digital representation model is deployed by a utility operator. For example, the digital representation model may use the repeated updates of the digital representation of the grid to continuously learn from the data associated from the measured portion of the grid and/or addition scenarios and simulated events.

Various types of machine learning models may be used for the digital representation model executed by digital twin 102. In some examples, the digital representation model may be including deep neural networks, long-short term memory (LSTM) models, convolutional neural networks, and extreme gradient boosting (XgBoost) supported models, or any other suitable model. In some examples, the digital representation model may be a graph neural network (GNN). The GNN may model various components of the grid, including power generators, power sinks, various DERs, and other components, as nodes of the GNN, and model the interconnectivity of the various components including cabling and open versus closed switches as lines of the GNN. As discussed above, the digital representation model may include multiple machine learning models each configured to perform one or more of the various functions described herein. In some examples, multiple machine learning models may each be configured to perform a portion of a function described herein, for example, one machine learning model per state as described with respect to the power flow or DSSE function.

Because of the various functions and operations of a power grid and the factors that go into power grid monitoring and orchestration, in some examples, the digital representation model may be a foundation model for the rest of the system and functions described herein. The foundation model may facilitate transfer learning from the foundation model executing the digital representation to represent a first circuit of the power grid to an updated model executing the digital representation to represent a second circuit. For example, the digital representation model executed by digital twin 102 generating a digital representation of a first circuit may be trained as described above, on a large number of simulated events, including historical data, so that it may accurately provide a digital representation of the grid. As such, the digital representation model may be updated to generate a digital representation of a second circuit and be made adaptable to switching and topology changes, including, but not limited to, the states of switches or the additional or removal of DERs, or any other suitable topology changes. For example, the second circuit may be a different portion of the power grid, or may include the first circuit with additional assets (e.g., new lines, cables, transformers, switch configurations, etc.) or have certain existing assets of the first circuit removed. The digital representation model may be used as a foundation model and may be fine-tuned to support grid topology changes and new grid components that may occur and arise throughout the lifetime of the grid. For example, the digital representation model may be trained on large networks, as discussed above, using a large number of simulated events. The digital representation model may then be more easily and inexpensively fine-tuned to account and be trained for additional smaller networks based at least in part on the training of the foundation model of the digital representation model.

In some embodiments, the digital representation model executed by the digital twin (and any other models described herein) may be trained centrally within enterprise data networks where data and computing power is broad and richly available. In that way, the models may be deployed decentrally in other portions of the grid. When deployed at one or more decentralized components of the grid (e.g., substation, smart meter), the models may be fine-tuned for local inferencing and data pre-processing and validation prior to transmitting the data back to the central model for bulk training and fine-tuning. These decentral deployments may provide high data frequency, quality, and fidelity and can enable performance of local high speed actions while the central bulk model is being further trained and fine-tuned.

Additionally or alternatively, the digital representation model executed by digital twin 102 may further be trained to analyze the digital representation to determine one or more operational metrics (e.g., if the grid is experiencing a violation, an asset is being over or underutilized), and/or trained to determine recommended relief actions to various metrics the grid may exhibit, as discussed below with respect to the insight, validation, and solution functionalities. In some examples, at least a subset of the simulated events that the digital representation model is trained on may be associated with a violation that the grid may be experiencing along with particular recommended relief actions associated with that violation. As such, one or more models of the digital representation model may be later fine-tuned to determine whether the grid is experiencing a violation and/or determine recommended relief actions for that violation.

Returning to method 330 of FIG. 3B, at act 336 a digital representation of the power grid may be generated based on the power flow information generated at act 334. For example, based power flow information, the digital representation model executed by digital twin 102 may generate digital representation 103 providing a nodal representation of each of the components of the power grid along with the measured or determined states of each of the components, as well as the interconnections therebetween.

In some embodiments, act 336 may comprise updating a previously generated digital representation of the power grid. In some examples, the digital representation model executed by digital twin 102 may update a digital representation, representing the state of the grid at a first point in time, to a digital representation, representing the state of the grid at a second point in time later than the first point in time. In some examples, the digital representation model may update the digital representation repeatedly, for example, every hour, every half hour, every minute, or over any other reasonable time period. In some examples, the digital representation model may update the digital representation every second, or every few seconds, so as to provide a digital representation of the state and operation of the grid in real time, or near-real time. In some examples, the system may implement, or may be in communication with a state forecasting system to provide and update the digital representation to represent a point in time that has not occurred yet. For example, the state forecasting system may use historical data of the grid, and optionally the current state of the grid, to determine an estimate of the future state of the grid.

Having generated the power flow information and the digital representation, the digital twin 102 may provide the power flow information and digital representation to other components of the system at act 338. For example, digital twin 102 may provide the power flow information and digital representation to the insight module 104, solution module 106, validation module 108, and/or user interface 110 for performing one or more of the respective modules' functions.

### Insight Functionality

The systems and techniques described herein may include at least one machine learning model configured to monitor and diagnose the operation of the power grid. In some examples, the insight module may be integrated with the digital representation model executed by digital twin 102, for example, as a portion of a machine learning model of the digital representation model. As such, the digital representation model, using the portion of the digital representation model, may perform the functions of the insight module described herein. In some examples, the digital representation model may be trained to monitor and diagnose the operation and state of the power grid as discussed below, in response to a user or operator interacting with the digital representation model. In some examples, the insight module may be a separate model. In some examples, when the insight module is a separate model, the insight module may be configured to receive the digital representation model as input to perform the functions of the insight module described herein.

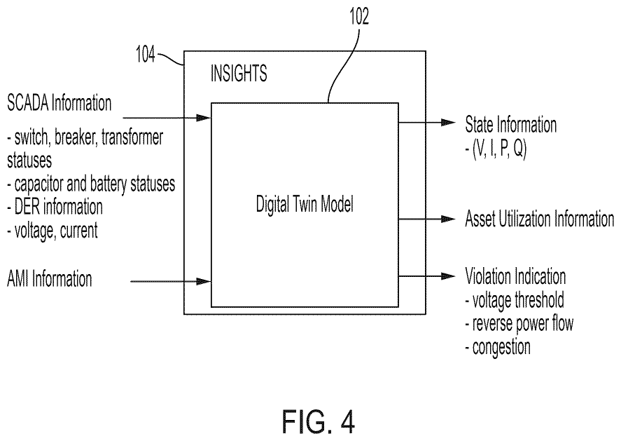

FIG. 4 depicts an example insight module 104 for performing autonomous power grid orchestration functions, according to some embodiments. In the illustrated embodiment, insight module 104 includes digital twin 102 executing a digital representation model (although it can be appreciated that these components may be executed separately). The insight module 104 is configured to receive information regarding the power grid, including topological information of the power grid, and various measured states of at least a subset of components of the power grid.

In some examples, the insight module 104 may cause the digital representation model to provide an updated digital representation of the grid as described in detail above. For example, the insight module 104 may cause the digital representation model to perform power flow modeling or DSSE functions every few seconds so as to monitor the states and operation of the grid in real time, or near-real time. In some examples, the insight module 104 may provide the data associated with the measured portion of the grid to the digital representation model to perform the power flow modeling or DSSE functions, for example, the data received from ADMS, SCADA, and/or AMI systems.

The insight module 104 may use the various outputs of the digital representation model to determine whether the grid is operating properly or is experiencing some violation or any other suitable operational metric. For example, the insight module 104 may determine that a component or portion of the grid is experiencing an overvoltage violation by determining that the voltage at that component or portion of the grid is higher than the voltage limit, or rating, of the component or portion of the grid. In other examples, the insight module 104 may determine that the grid is experiencing a reverse power flow by monitoring the power flow of various portions of the grid. Accordingly, the insight module 104 may output the various states of the grid (e.g. real power, reactive power, current, voltage) and other operational metrics such as asset utilization and determined violations, or any other suitable monitoring and diagnostic information, to be used by other portions of the system.

### Solution Functionality

The systems and techniques described herein may include at least one machine learning model configured determine recommended actions for optimizing function and operation of the power grid, as well as mitigating various violations the grid may be experiencing. In that way, the systems and techniques described herein may provide a proactive assessment of grid efficiency to provide actions to optimize operation of the grid and recommend improvements for optimizing design and dispatch of various components of the grid as well as provide recommended relief actions when the grid exhibits an operational violation.

In some examples, the solution model may be integrated with the digital representation model, for example, as a portion of a machine learning model of the digital representation model. As such, the digital representation model, using the portion of the digital representation model, may perform the functions of the solution model described herein. In some examples, the solution model may be a separate model. In some examples, when the solution model is a separate model, the solution model may be configured to receive the digital representation model and the various determined outputs of the insight module as input to perform the functions of the solution model described herein.

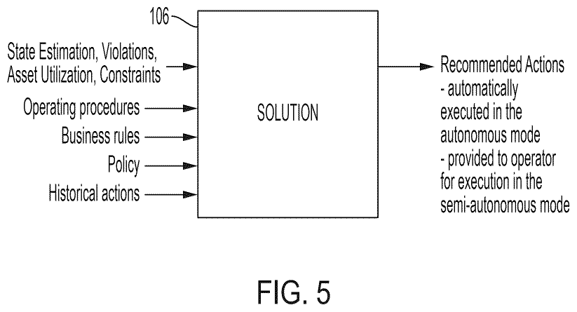

FIG. 5 depicts an example solution module 106 for performing autonomous power grid orchestration functions, according to some embodiments. In the illustrated embodiment, solution module 106 may execute one or more machine learning models (referred to herein as a solution model) configured to determine recommended actions. For example, the solution module may receive information generated by the insight module 104 described above with respect to the power flow model or DSSE, operational violations, and asset utilization and constraints. In some embodiments, when the power grid is experiencing an operational violation, determining the recommended actions may include determining one or more recommended relief actions to address the operational violation

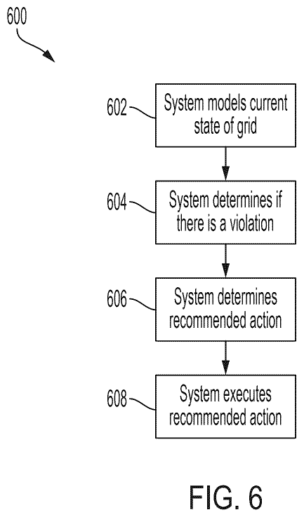

FIG. 6 depicts an example method 600 for autonomous orchestration of a power grid experiencing an operational violation, according to some embodiments. Method 600 begins at act 602 with the system modelling the current state of the grid. Act 602 may be performed by the digital representation model executed by digital twin 102 as described above. For example, insight module 104 may request an updated digital representation (e.g., digital representation 103) from digital twin 102. The digital twin 102 may provide insight module 104 the digital representation along with the power flow information used to generate the digital representation.

At act 604, the system determines whether the power grid is experiencing a violation based upon the updated digital representation and/or the power flow information received from digital twin 102. For example, insight module 104 may determine that the voltages at one or more components of the power grid are higher than the rated limits of the particular components. Thus, insight module 104 may determine that those components are experiencing an overvoltage violation. Other violations as noted above include reverse power flow violations, current violations, asset over or under utilization, or any other suitable operational violation.

At act 606, the system may then determine one or more recommended actions. For example, the system may determine one or more recommended actions to optimize operation of the power grid based on the digital representation and the operational states determined at act 602. Optimizing the power grid may comprise reducing congestion in portions of the power grid, changing the topology (e.g., flipping switches, disconnecting particular DERs) of the power grid, deploying personnel to components of the power grid operating suboptimally, dispatch of grid devices (e.g., capacitors, voltage regulators, tap changers), or wire solutions including adding (or removing) lines, cables, transformers, and/or switching devices for grid expansion and grid reinforcement solutions, or any other suitable act to optimize the operation of the power grid. In some embodiments, when the system determines at act 604 that the power grid is experiencing an operational violation, determining the one or more recommended actions may comprise determining one or more recommended relief actions to address and mitigate the operational violation. In some embodiments, insight module 104 may provide information associated with the determined violation(s) to solution module 106. For example, insight module 104 may provide an indication of the determined violation(s) along with power flow information (topological information, state information, power flow information) that led to the determination.

The solution module 106 may execute a machine learning model configured to determine the one or more recommended actions. Solution module 106 may provide the information received from insight module 104 as input to a solution model (one or more machine learning models) executed by the solution module 106. The solution model may be configured to determine the one or more recommended actions based on the information received from insight module 104 (state estimation, violations, asset utilization, constraints). In some embodiments, the solution model may additionally account for other information including operating procedures, business rules, policy, and historical actions.

As discussed above with respect to the digital representation model, the solution model may be trained on a large number of simulated events including historical events, real-time events, forecasted events, and synthetic scenarios. As such, the solution model may be pretrained based on the simulated events with various operational actions, including operational optimization actions, switching, grid reconfiguration, flexibility management, congestion management constraint management, violation management, contingency management, planned work management, outage management, resiliency management, storm management, adverse event management, optimal dispatch, energy resource interconnection, and market or program pricing adjustments.

In some examples, the solution model may further be trained to utilize other relevant information in determining the recommended actions. For example, the solution model may use as input during training: standard operating practices, business rule and policies, and previous user operations to aid in determining the proper actions. In that way, in some embodiments, the solution model may be configured to generate both technical or techno-economic solutions including, but not limited to, capital plans, maintenance plans, operational plans, and/or capital investment portfolios. As an illustrative example, the insight model may determine that the grid is experiencing a reverse power flow. The solution model may use the indication of the reverse power flow, along with standard operating practices, business rules and policies, and previous user operations to determine which relief actions of the trained relief actions may be suitable to mitigate the reverse power flow, for example, reconfiguring the grid may help mitigate the reverse power flow violation or replacing a particular type of component with a new or updated version of the component.

In some examples, the solution model may continuously learn based on real-time situations after being deployed. In some examples, the solution model may continuously learn using reinforcement learning or reinforcement learning with human feedback as it determines recommended relief actions for various grid violations or other operational metrics throughout its operation.

Having determined the one or more recommended actions, at act 608, the system may execute at least one of the one or more recommended actions. The actions may include controlling one or more components of the power grid from an operating station, deploying personnel to one or more components experiencing a violation, disconnecting one or more components from the power grid, or any other suitable recommended action.

As discussed further below with respect to the UI/UX functionality of the system, the system may execute the recommended action in one of a number of modes including but not limited to semi-autonomous, supervised autonomous, and/or autonomous modes. In the semi-autonomous mode, the system may present the recommended relief action to an operator using the system to monitor and diagnose the grid and the operator may approve the recommended action before the action is executed. In the supervised autonomous mode, the recommended action may similarly be presented to the operator. However, the recommended action may be executed autonomously. In some examples, the supervised autonomous mode may provide the operator with an option to pause the system so that the operator may review the recommended action before it is executed. In the autonomous mode, the system may not present the recommended action to the operator before executing the recommended action. After the action is executed, the insight model of the system may confirm that a violation has been resolved or other operational state has been addressed (e.g., optimized) by requesting an updated digital representation of the grid from the digital representation model.

### Validation Functionality

Given that certain aspects of monitoring, diagnosing, and mitigating various operations and violations of the power grid present certain dangers, for example, linemen working closely with high voltage power lines, it may be important to ensure that the models of the system described herein remain accurate, so as to minimize the risk of danger and harm to lineman working on the electrical components of the power grid. However, manual and rules-based validation, as is traditionally done, may be inefficient, increasing operational expenses and resulting in sub-optimal actions, conservatism, risks to safety, reliability, and quality of service. Thus, validation may be important to maintaining the reliability of traditional engineering analytics, as well as the analytics of the system described herein. As such, the inventors have developed systems and techniques for validating the various models of the systems described herein.

In some examples, one or more of the models described herein (e.g. digital representation model) may be validated by actively perturbing the model with various known errors and observing the impacts caused by the perturbation. FIG. 7 depicts an example validation module for performing autonomous power grid orchestration functions, according to some embodiments. In the illustrated embodiment, validation module 108 includes digital twin 102 executing the digital representation model. However, it can be appreciated that in other embodiments, digital twin 102 and validation module 108 may be executed separately. The validation module may include one or more machine learning models (referred to herein as a validation model) configured to determine error metrics associated with the digital representation model executed by digital twin 102. The validation model may be a portion of the digital representation model or may be executed separately.

The validation model may be trained with perturbations and variations of an engineering model to identify and/or correct potential location, types, and degree of error in source data of the model, including but not limited to assets, connectivity, asset parameters, phasing, and topology, to validate the various models of the system described herein, including error baselining, diagnosis, correction, and calibration. For example, the system may compare the digital representation of the grid provided by the digital representation model with a physics-based model representing the grid for example as it was built or operated. The system may perturb both the digital representation model and the physics-based model with known errors and may observe the different output patterns, for example, the differences observed in the power flow (or any other suitable metric described herein, e.g., switch topology, asset utilization, etc.) between the digital representation model and the physics-based model. This comparison may be used to determine a model error metric which may be expressed as a percent error. Additionally or alternatively, in some embodiments, grid measurements (e.g., SCADA data or metering information) may be used to provide ground truth sources to validate the models.

The model error metric in some examples, may be a composite metric including the errors of the various states (e.g. real power, current, etc.) at each node, feeder of the grid, or medium voltage measurement point of the grid and may encompass a circuit region surrounding that point and may include a model error metric for each phase of the three phase alternating current. In some examples, the model error metric may be calculated per feeder, downstream of a substation breaker of the grid. In some examples, switch configurations of the grid may similarly be validated, for example, through classifying the different measurements and state estimations with a number of potential switch configurations.

The model error metric may be used to determine whether the model is valid. For example, the model error metric, expressed as a percent, may be compared to a threshold percent error for example, 2% error or 5% error. The validation module 108 may determine that the model is valid when the model error metric is below the threshold percent error and invalid if equal to or above the threshold percent error. In some examples, the validation module 108 may calculate a confidence interval for the model error metric. The validation module 108 may determine that the model is valid when the confidence interval encompasses a zero percent error. In some examples, the validation module 108 may determine that the model is valid when the model error metric is below a threshold percent error and the confidence interval of the model error metric encompasses zero percent error. As discussed above, the model error metric may be calculated per node, per feeder, etc. In some examples, the system may determine that the model is valid only if all the model error metrics and/or confidence intervals satisfy the above-described requirements.

In determining that the models of the system may not be valid, validation module 108 may further be configured to provide recommendations for correcting the model. In some examples, the validation model may be further configured to perform this functionality. In some examples, a separate model of the system may be configured to perform this functionality. The model may be trained to determine and provide recommendations for correcting the model based on asset libraries, network designs, and prior engineering experience. In some embodiments, the model may be a large language model trained on and continuously learning from the asset libraries, network designs, and prior engineering experiences.

The validation module 108 may use the model error metric, as described above, to determine various recommendations for correcting the model. For example, the validation module 108 may provide recommendations for correcting network topology such as the status of switches, or whether switches are manual versus remote controlled. Other recommendations may include, but are not limited to, correcting the phasing of assets, such as which phase single phase loads are connected to (e.g. of the three phase AC power flow), asset parameters such as cable impedances, asset connectivity such as which asset is connected to which node of the network, and adding new or undetected assets, such as jumpers, grounds, and new DERs. The recommendations may be presented to an operator of the system. In some examples, the recommendations may be implemented autonomously without operator input. In some examples, the recommendations may require operator approval to be implemented as a form of supervised validation. In some examples, the validation model may be continuously learn based on real time data including new data errors and recommendations for clean-up. In some examples, operator feedback may be used by the validation model to support this continuous learning.

### UI/UX Functionality

In some examples, the inventors have recognized that it may be beneficial to provide a user interface for the system to allow an operator of the grid to monitor and verify the various calculations and actions taken by the system in monitoring the state and operation of the grid. The system may include a display for displaying the user interface to an operator of the grid, and a processor to receive information to be displayed in the user interface and cause the user interface to display the received information. The processor may receive any of the information, data, and outputs of the models of the system that the system may use to monitor the state and operation of the grid.

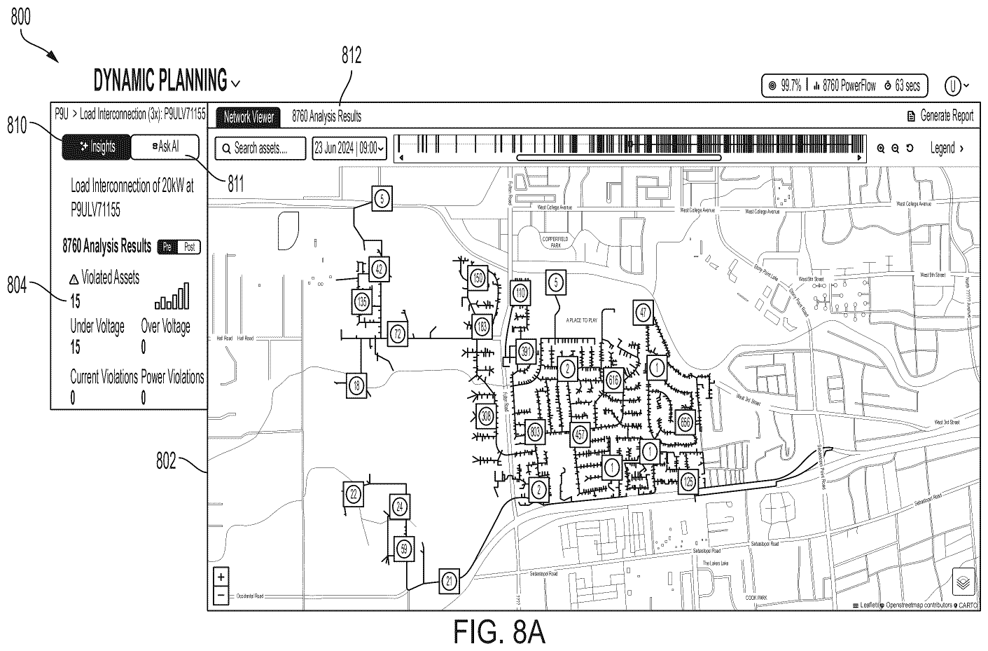

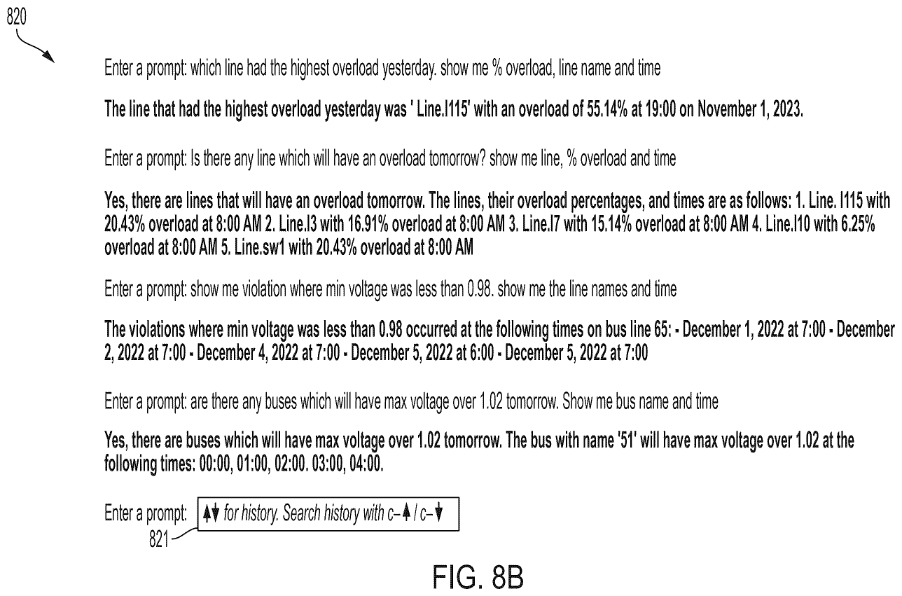

FIG. 8A depicts an example user interface 800 for performing autonomous power grid orchestration functions, according to some embodiments. In the illustrated embodiment, user interface 800 includes a visual representation 802 of the power grid (or a section thereof), a violation dashboard 804, and various selectable visual indicators 810-812 (e.g., buttons, tabs, toggles, sliders) for performing various functions of user interface 800 and the system.

The user interface 800 includes a visual representation of the grid as modeled by the digital representation model. The visual representation may include a map of the area of responsibility for the digital representation model and may overlay the various nodes and lines connecting the nodes onto the map to provide an accurate visual representation 802 of the grid within the area of responsibility for the digital representation. In some examples, the visual representation 802 may be updated every time the digital representation model provides an updated digital representation of the grid. The visual representation 802 may include other information determined by the various models of the system. For example, the visual representation 802 may include information about the various nodes of the model, including the states of the component at that node, utilization, ratings, and any other suitable information. This information may be provided for example, in a dashboard form, with color in visual representation 802, or as an overlay, for example, when an operator hovers a selector over a particular node in the visual representation 802.

If the insight model determines that the grid is experiencing a violation, the visual representation 802 may similarly be updated to indicate that a violation is being experienced. For example, the insight model may determine the portion of the grid that is experiencing the violation and the visual representation 802 may be updated to indicate that portion of the grid in a different color, and additionally or alternatively, may display information associated with the violation including the type of violation, the duration of the violation, the customers affected by the violation, the priority of the violation, and any other suitable information associated with the violation.

Additionally or alternatively, the user interface 800 may display the various information in a list or a group of lists (e.g., as a dashboard). For example, the user interface 800 may display in a first list, the various calculations and modelling operations that the models of the system may be conducting as they are being conducted. The user interface 800 may display in a second list, the various violations that the grid may be experiencing at any given point in time. For example, as illustrated, user interface 800 includes violation dashboard 804 which is configured to display various information associated with determined violations. The information associated with the determined violations may include a total number of violations, type of violations, timing of various violations, magnitude of various violations, or any other suitable information (although not all of the information is depicted in FIG. 8A). In some examples, the user interface may display the violations in the second list in a prioritized order determined, for example, by the insight model or another model of the system.

As in the illustrated embodiment, the power flow information and violations determined by the insight module may be displayed in more than one area of user interface 800. For example, violation dashboard 804 may provide a brief summary of the various violations that the power grid is experiencing. However, user interface 800 may include one or more other regions for displaying more detailed information regarding the power flow information and violation(s). In the illustrated embodiment, selectable visual indicator 812 may cause user interface 800 to display more complete power flow information and violation information, as well as any recommended relief actions for the violations. Selectable visual indicator 812 may cause visual representation 802 to be replaced with the power flow information and violation information, or may cause the power flow information and violation information to be displayed adjacent to visual representation 802 or in a separate window.

The user interface may display in a third list, the recommended relief actions determined by the solution model. In some examples, the user interface may display all of the recommended relief actions for each of the violations or may display only the top recommended relief action for each of the violations. In some examples, the user interface may only display all or the top recommended relief action for the highest priority violation. In some examples, the second list and the third list may be combined to display the violations and recommended relief actions together and associate the recommended relief actions with the relevant violation. The user interface may also display various alerts determined by the models of the system. For example, the insight model may determine various violations, power flow congestion, low asset utilization, or other alerts to be displayed by the user interface. The solution model may determine that there may not be a suitable recommended relief action and/or the grid is at risk, and the user interface may display an alert indicating as such. The validation model may determine that model error is high and that the data, model, and recommended relief actions should not be trusted, and the user interface may display an alert indicating as such.

As discussed above, the system may support various modes of monitoring the state and operation of the grid. For example, an execution module (e.g., executed by any of the processors described herein) of the system may run in a semi-autonomous mode that may autonomously monitor and diagnose various metrics and violations regarding the state and operation of the grid, but may require operator input or approval to execute any recommended relief actions determined to mitigate the various violations the grid may experience in response to the operator viewing the various metrics and violations determined by the system.

The execution module may run in a supervised autonomous mode that is substantially similar to the semi-autonomous mode, except that the supervised autonomous mode may present the recommended relief actions determined by the system to an operator but may also execute the recommended relief actions without any operator input or approval. The user interface may allow the operator however to pause the supervised autonomous mode prior to the recommended relief action being executed so that the operator may review the recommended relief action. In any of the modes described above, the user interface may additionally or alternatively allow the user to select between various options on actions in response to the operator viewing the various options and providing input. For example, the various options on actions may include different objectives for particular actions, weight different objectives determined for a single action, identify risk and rewards of various actions. In some examples, the various options may allow the user to modify and/or override actions before they are to be executed.

The user interface may include various components (e.g., selectable visual indicators) to allow toggling between the semi-autonomous and supervised autonomous modes of the system or may provide a prompt on opening the user interface requesting whether to run the system in one or the other modes.

As further discussed above, the aging workforce and labor shortage for technically skilled operators with high levels of experience may mean younger operators with less experienced may be integrated into the workforce. These younger operators may not have the technical experience to recognized some of the more nuanced issues and problems the grid may experience, or the system may recognize. As such, providing a chat interface as part of the user interface may help support younger operators learn the nuances of the system and gain experience to increase the learning curve and can help support any operators using the system. FIG. 8B depicts an example chat interface 820 for performing autonomous power grid orchestration functions, according to some embodiments. Chat interface 820 may be executed by a chat module of the system and is configured to enable operator interaction with the system, for example, through text input field 821, as well as other forms of input (e.g., buttons, sliders, cursor hovering) not depicted.

Chat interface 820 may be integrated with user interface 800 in any suitable manner. For example, in the illustrated embodiment, chat interface 820 may be accessed by an operator upon selection of selectable visual indicator 811 (“Ask AI”). In other embodiments, chat interface 820 may be displayed adjacent to visual representation 802 and/or violation dashboard 804. In other embodiments, chat interface 820 may be displayed in a separate window than visual representation 802 and violation dashboard 804.

In some examples, chat interface 820 may be supported by a machine learning model, for example, a large language model (LLM), large action model (LAM), or any other suitable machine learning model for the operator to interact with and provide accurate and detailed responses to support the operator in monitoring and understanding the various components and issues with the grid. For example, the machine learning model may be similarly trained on various simulated events as well as previous operator inquiries and uses to be able to pull relevant information that the current operator may request. In some examples, to support younger and less experienced operators, the machine learning model of chat interface 820 may further provide recommended prompts to the operator that the operator may lack the experience to capture themselves. In some examples, chat interface 820 may additionally display any of the metrics or states described above to be generated by the system (e.g., power flow information, violations, etc.). For example, chat interface 820 may display one or more of the violations determined as described above in a text-based chat format. In some examples, the metrics or states may be displayed in a dashboard as described above, where the dashboard (e.g., violation dashboard 804) is integrated with the chat interface 820.

It can be appreciated that a text-based or dashboard format may not alone be suitable for high priority operations. As such, in some examples, the chat interface may be synchronized with a network viewer. In some examples, the network viewer may display the digital representation as described above. In some examples, the network viewer may comprise a geospatial interface for displaying the digital representation and/or one or more of the various metrics described herein. In doing so, the chat interface may provide a more effective display for an operator to view and base decisions on.

FIG. 9 depicts an example computer-based system on which the system of FIG. 1 may be implemented, according to some embodiments. The computer system 900 includes one or more computer hardware processors 902 and one or more articles of manufacture that comprise non-transitory computer-readable storage media (e.g., memory 904 and one or more non-volatile storage devices 906). The processor(s) 902 may control writing data to and reading data from the memory 904 and the non-volatile storage device(s) 906 in any suitable manner. To perform any of the functionality described herein, the processor(s) 902 may execute one or more processor executable instructions stored in one or more non-transitory computer-readable storage media (e.g., the memory 904), which may serve as non-transitory computer-readable storage media storing processor-executable instructions for execution by the processor(s) 902.

In some embodiments, computer system 900 also includes a user interface 908 (e.g., for displaying user interface 800) in communication with processor(s) 902. The user interface 908 may be configured to display any information generated by the different modules described herein as executed by processor(s) 902.

It can be appreciated that the various modules and functionality described herein may be implemented and combined in any suitable manner. For example, the different modules may be executed as one or more agents configured to perform the various functions described herein.

In some embodiments, one or more of the modules described herein may be executed as planning agent configured to monitor and control planning of the power grid. For example, the planning agent may be configured to determine the various interconnections between different components of the power grid, manage different components of the power grid, and/or determine and model transmission and distribution of power throughout the power grid.

In some embodiments, one or more of the modules described herein may be executed as an operational planning agent configured to monitor and control the operation of the power grid. For example, the operational planning agent may be configured to determine one or more actions (e.g., with the solution module) to determine and control power flow throughout the power grid. In some embodiments, the operational planning agent may determine actions to control the power flow one or more days or weeks ahead of executing the actions. The operational planning agent may be further configured to perform contingency analysis to plan for unanticipated operational events or violations (e.g., using the insight and/or solution modules), or may control how DERs may be connected with the power grid.

In some embodiments, one or more of the modules described herein may be executed as and operational agent configured to determine the operational states of the power grid and actions in response to the operational states in real-time or near-real time, for example, using the insight and solution modules. In that way, the operational agent may be configured to determine and control operations of the power grid in real-time or near-real time.

In some embodiments, one or more of the modules described herein may be executed as distributed agents configured to determine and control operation of a subsection of the power grid. Multiple distributed agents may operate in tandem to control operation of various portions of the power grid. For example, a distributed agent may be configured to monitor and control operation of a portion of the power grid that a particular substation of the grid is responsible for. In some embodiments, the distributed agents may be responsible for monitoring and controlling the edges of the power grid, for example, DERs connected to the power grid.

In some embodiments, it should be appreciated that one or more agents may be instantiated, at least one of which having an associated AI/ML model configured to receive one or more signals responsive to actual grid measurements, computed and/or estimated values. These agents may be, in some embodiments, autonomous and/or semi-autonomous agents responsive to the actual grid measurements, computed and/or estimated values. In some embodiments, AI/ML models may be centrally trained where data and compute power is broad and richly available, and deployed remotely (e.g., within the grid and/or at edges) as IoT for local inferencing as well as fine-tuning, where the frequency, quality and fidelity if data can be higher, and local high speed resilient actions can be performed. Further, remote data can be pre-processed (e.g., validated) before sending data back to the central enterprise for bulk training and fine tuning. In this manner, compute resources including processing and bandwidth usage may be optimized.

Having thus described several aspects of at least one embodiment of the technology described herein, it is to be appreciated that various alterations, modifications, and improvements will readily occur to those skilled in the art. Such alterations, modifications, and improvements are intended to be part of this disclosure and are intended to be within the spirit and scope of disclosure. Further, though advantages of the technology described herein are indicated, it should be appreciated that not every embodiment of the technology described herein will include every described advantage. Some embodiments may not implement any features described as advantageous herein and in some instances one or more of the described features may be implemented to achieve further embodiments. Accordingly, the foregoing description and drawings are by way of example only.

The above-described embodiments of the technology described herein can be implemented in any of numerous ways. For example, the embodiments may be implemented using hardware, software, or a combination thereof. When implemented in software, the software code can be executed on any suitable processor or collection of processors, whether provided in a single computer or distributed among multiple computers. Such processors may be implemented as integrated circuits, with one or more processors in an integrated circuit module, including commercially available integrated circuit modules known in the art by names such as CPU chips, GPU chips, microprocessor, microcontroller, or co-processor. Alternatively, a processor may be implemented in custom circuitry, such as an ASIC, or semicustom circuitry resulting from configuring a programmable logic device. As yet a further alternative, a processor may be a portion of a larger circuit or semiconductor device, whether commercially available, semicustom or custom. As a specific example, some commercially available microprocessors have multiple cores such that one or a subset of those cores may constitute a processor. However, a processor may be implemented using circuitry in any suitable format.

Also, the various methods or processes outlined herein may be coded as software that is executable on one or more processors that employ any one of a variety of operating systems or platforms. Additionally, such software may be written using any of a number of suitable programming languages and/or programming or scripting tools, and also may be compiled as executable machine language code or intermediate code that is executed on a framework or virtual machine.

In this respect, aspects of the technology described herein may be embodied as a computer readable storage medium (or multiple computer readable media) (e.g., a computer memory, one or more floppy discs, compact discs (CD), optical discs, digital video disks (DVD), magnetic tapes, flash memories, circuit configurations in Field Programmable Gate Arrays or other semiconductor devices, or other tangible computer storage medium) encoded with one or more programs that, when executed on one or more computers or other processors, perform methods that implement the various embodiments described above. As is apparent from the foregoing examples, a computer readable storage medium may retain information for a sufficient time to provide computer-executable instructions in a non-transitory form. Such a computer readable storage medium or media can be transportable, such that the program or programs stored thereon can be loaded onto one or more different computers or other processors to implement various aspects of the technology as described above. A computer-readable storage medium includes any computer memory configured to store software, for example, the memory of any computing device such as a smart phone, a laptop, a desktop, a rack-mounted computer, or a server (e.g., a server storing software distributed by downloading over a network, such as an app store)). As used herein, the term “computer-readable storage medium” encompasses only a non-transitory computer-readable medium that can be considered to be a manufacture (i.e., article of manufacture) or a machine. Alternatively, or additionally, aspects of the technology described herein may be embodied as a computer readable medium other than a computer-readable storage medium, such as a propagating signal.

The terms “program” or “software” are used herein in a generic sense to refer to any type of computer code or set of processor-executable instructions that can be employed to program a computer or other processor to implement various aspects of the technology as described above. Additionally, it should be appreciated that according to one aspect of this embodiment, one or more computer programs that when executed perform methods of the technology described herein need not reside on a single computer or processor, but the processor functions may be distributed in a modular fashion among a number of different computers or processors to implement various aspects of the technology described herein.

Computer-executable instructions may be in many forms, such as program modules, executed by one or more computers or other devices. Generally, program modules include routines, programs, objects, modules, data structures, etc. that perform particular tasks or implement particular abstract data types. Typically, the functionality of the program modules may be combined or distributed as desired in various embodiments.

Also, data structures may be stored in computer-readable media in any suitable form. For simplicity of illustration, data structures may be shown to have fields that are related through location in the data structure. Such relationships may likewise be achieved by assigning storage for the fields with locations in a computer-readable medium that conveys relationship between the fields. However, any suitable mechanism may be used to establish a relationship between information in fields of a data structure, including through the use of pointers, tags or other mechanisms that establish relationship between data elements.

Various aspects of the technology described herein may be used alone, in combination, or in a variety of arrangements not specifically described in the embodiments described in the foregoing and is therefore not limited in its application to the details and arrangement of modules set forth in the foregoing description or illustrated in the drawings. For example, aspects described in one embodiment may be combined in any manner with aspects described in other embodiments.

Also, the technology described herein may be embodied as a method, of which examples are provided herein. The acts performed as part of any of the methods may be ordered in any suitable way. Accordingly, embodiments may be constructed in which acts are performed in an order different than illustrated, which may include performing some acts simultaneously, even though shown as sequential acts in illustrative embodiments.

All definitions, as defined and used herein, should be understood to control over dictionary definitions, definitions in documents incorporated by reference, and/or ordinary meanings of the defined terms.

The indefinite articles “a” and “an,” as used herein in the specification and in the claims, unless clearly indicated to the contrary, should be understood to mean “at least one.”

The phrase “and/or,” as used herein in the specification and in the claims, should be understood to mean “either or both” of the elements so conjoined, i.e., elements that are conjunctively present in some cases and disjunctively present in other cases. Multiple elements listed with “and/or” should be construed in the same fashion, i.e., “one or more” of the elements so conjoined. Other elements may optionally be present other than the elements specifically identified by the “and/or” clause, whether related or unrelated to those elements specifically identified. Thus, as a non-limiting example, a reference to “A and/or B,” when used in conjunction with open-ended language such as “comprising” can refer, in one embodiment, to A only (optionally including elements other than B); in another embodiment, to B only (optionally including elements other than A); in yet another embodiment, to both A and B (optionally including other elements); etc.

As used herein in the specification and in the claims, the phrase “at least one,” in reference to a list of one or more elements, should be understood to mean at least one element selected from any one or more of the elements in the list of elements, but not necessarily including at least one of each and every element specifically listed within the list of elements and not excluding any combinations of elements in the list of elements. This definition also allows that elements may optionally be present other than the elements specifically identified within the list of elements to which the phrase “at least one” refers, whether related or unrelated to those elements specifically identified. Thus, as a non-limiting example, “at least one of A and B” (or, equivalently, “at least one of A or B,” or, equivalently “at least one of A and/or B”) can refer, in one embodiment, to at least one, optionally including more than one, A, with no B present (and optionally including elements other than B); in another embodiment, to at least one, optionally including more than one, B, with no A present (and optionally including elements other than A); in yet another embodiment, to at least one, optionally including more than one, A, and at least one, optionally including more than one, B (and optionally including other elements); etc.

In the claims, as well as in the specification above, all transitional phrases such as “comprising,” “including,” “carrying,” “having,” “containing,” “involving,” “holding,” “composed of,” and the like are to be understood to be open-ended, i.e., to mean including but not limited to. Only the transitional phrases “consisting of” and “consisting essentially of” shall be closed or semi-closed transitional phrases, respectively.

The terms “approximately” and “about” may be used to mean within ±20% of a target value in some embodiments, within ±10% of a target value in some embodiments, within ±5% of a target value in some embodiments, within ±2% of a target value in some embodiments. The terms “approximately” and “about” may include the target value.

Use of ordinal terms such as “first,” “second,” “third,” etc., in the claims to modify a claim element does not by itself connote any priority, precedence, or order of one claim element over another or the temporal order in which acts of a method are performed, but are used merely as labels to distinguish one claim element having a certain name from another element having a same name (but for use of the ordinal term) to distinguish the claim elements.

What is claimed is:

1. A system for facilitating monitoring and orchestration of operations and planning of a power grid, the system comprising:
a digital representation of the power grid having a plurality of nodes and a plurality of lines connecting the plurality of nodes, each node of the plurality of nodes representing a respective electrical component of the power grid and each line of the plurality of lines representing an electrical connection between respective electrical components of the power grid; and
one or more machine learning models configured to:
execute the digital representation of the power grid;
determine an operational state of the power grid by:
receiving as input, data associated with at least a subset of the plurality of nodes wherein the data is indicative of a state of each node of the subset of the plurality of nodes; and
determining a state of each node of the plurality of nodes based at least in part on the received data associated with at least a subset of the plurality of nodes; and
cause the digital representation of the power grid to update based on the determined operational state of the power grid.

2. The system of claim 1, wherein the one or more machine learning models are further configured to cause the digital representation of the power grid to update substantially in parallel with the operations of the power grid.

3. The system of claim 1, wherein at least one of the one or more machine learning models is trained on a plurality of scenarios including at least one of: historical scenarios, real time scenarios, forecasted scenarios and/or synthetic scenarios.

4. The system of claim 3, wherein the at least one of the one or more machine learning models is further configured to learn continuously based at least in part on the received data and/or one or more scenarios of the plurality of scenarios.

5. The system of claim 1, wherein the one or more machine learning models are further configured to determine one or more actions for operating the power grid based on the determined operational state of the power grid.

6. The system of claim 5, wherein the one or more actions include at least one relief action responsive to the determined operational state of the power grid when the determined operational state of the power grid indicates that the power grid is experiencing an operational violation.

7. The system of claim 6, wherein the at least one relief action is determined in response to an indication that the power grid is experiencing at least one of: an overvoltage violation, and undervoltage violation, a reverse power flow, and/or a current violation.

8. The system of claim 5, wherein determining one or more actions for operating the power grid based on the determined operational state of the power grid comprises using at least one of the one or more machine learning models trained using one or more of: standard operating practices, business rules, policies, and/or previous user experiences.

9. The system of claim 1, wherein at least one of the one or more machine learning models configured to execute the digital representation is a physics-informed machine learning model trained using a physics-based engineering model.

10. The system of claim 9, wherein the physics-informed machine learning model is a Graph Neural Network (GNN).

11. The system of claim 9, wherein:
the physics-informed machine learning model is a foundational model trained on a first training data set to execute the digital representation of the power grid to represent a first circuit; and
the physics-informed machine learning model is further configured to be updated to execute the digital representation of the power grid to represent a second circuit by further training the physics-informed machine learning model on a second training data set having less training data than the first training data set.

12. The system of claim 1, further comprising a forecasting tool, wherein the one or more machine learning models configured to execute the digital representation of the power grid is configured to use the forecasting tool as input to execute a predicted digital representation of the power grid by determining a predicted operational state of the power grid and causing the digital representation of the power grid to update based on the predicted operational state of the power grid.

13. The system of claim 1, wherein the one or more machine learning models are further configured to validate the digital representation of power grid.

14. The system of claim 13, wherein validating the digital representation of the power grid comprises simulating an event with a known outcome on the digital representation to determine a model outcome and comparing the model outcome with the known outcome.

15. The system of claim 14, wherein comparing the model outcome with the known outcome comprises determining an error metric and a confidence interval for each node of the plurality of nodes of the digital representation.

16. The system of claim 15, wherein the digital representation is validated when the error metric is below a certain threshold and/or the confidence interval encompasses a zero percent error.

17. A method for facilitating monitoring and orchestration of operations and planning of a power grid, the method comprising:
receiving data associated with at least a subset of a plurality of nodes of the power grid, the data being indicative of a state of each node of the subset of the plurality of nodes;
providing the received data as input to one or more machine learning models configured to generate a digital representation of the power grid to determine an operational state of the power grid; and
generating, using the one or more machine learning models, a digital representation of the power grid based on the determined operational state of the power grid.

18. The method of claim 17, wherein the one or more machine learning models are pre-trained on a central network grid and further fined-tuned on a decentral subset of the grid when deployed at one or more components of the grid.

19. The method of claim 17, the method further comprising:
updating the digital representation of the power grid when new data associated with the subset of the plurality of nodes of the power grid is received, wherein updating the digital representation is performed substantially in parallel with operations of the power grid.

20. A non-transitory computer-readable medium storing computer executable instructions that when executed by a processor, cause the processor to perform a method for facilitating monitoring and orchestration of operations and planning of a power grid, the method comprising:
receiving data associated with at least a subset of a plurality of nodes of the power grid, the data being indicative of a state of each node of the subset of the plurality of nodes;
providing the received data as input to one or more machine learning models configured to generate a digital representation of the power grid to determine an operational state of the power grid; and
generating, using the one or more machine learning models, a digital representation of the power grid based on the determined operational state of the power grid.
